(19) United States
(12) Patent Application Publication
(10) Pub. No.: US 2010/0320506 A1
(43) Pub. Date: Dec. 23, 2010

(54) Ultra-Low Dislocation Density Group III - Nitride Semiconductor Substrates Grown Via Nano- Or Micro-Particle Film

(75) Inventors: Petros M. Varangis, Rio Rancho, NM (US); Lei Zhang, Rio Rancho, NM (US)

Correspondence Address: FENWICK & WEST LLP, SILICON VALLEY CENTER, 801 CALIFORNIA STREET, MOUNTAIN VIEW, CA, 94041, US

(73) Assignee: Nanocrystal Corporation, Rio Rancho, NM (US)

(21) Appl. No.: 12/743,359

(22) PCT Filed: Nov. 25, 2008
(86) PCT No.: PCT/US08/84763

§ 371 Date: Aug. 24, 2010

Related U.S. Application Data
(60) Provisional application No. 61/004,485, filed on Nov. 27, 2007.
(60) Provisional application No. 61/007,785, filed on Dec. 13, 2007.
(60) Provisional application No. 61/021,596, filed on Jan. 16, 2008.

(51) Int. Cl. H01L 29/06; H01L 21/04; H01L 29/12

(52) U.S. Cl. 257/201; 438/478; 257/615; 257/183; 257/E21.04; 257/E29.005; 257/E29.068

(57) ABSTRACT

A high quality Group III-Nitride semiconductor crystal with ultra-low dislocation density is grown epitaxially on a substrate via a particle film with multiple vertically-arranged layers of spheres with innumerable micro- and/or nano-voids formed among the spheres. The spheres can be composed of a variety of materials, and in particular silica or silicon dioxide (SiO2).

### CROSS-REFERENCE TO RELATED APPLICATION(S)

This application claims priority under 35 U.S.C. §119(e) to U.S. Provisional Patent Application Ser. No. 61/004,485, “Manufacturing of Ultra-Low Dislocation Density Group III-Nitride Semiconductor Substrate Based on Epitaxial Growth via Particle Film with Micro-voids,” filed Nov. 27, 2007; Ser. No. 61/007,785, “Manufacturing of Ultra-Low Dislocation Density Group III-Nitride Semiconductor Substrate Based on Epitaxial Growth via Particle Film with Micro- or Nano-Spheres,” filed Dec. 13, 2007; and Ser. No. 61/021,596, “Ultra-Low Dislocation Density Group III-Nitride Semiconductor Substrates Grown Via Nano- or Micro-Particle Film,” filed Jan. 16, 2008. The subject matter of all of the foregoing is incorporated herein by reference in their entirety.

### BACKGROUND OF THE INVENTION

1. Field of the Invention

The present invention relates to a high quality Group III-Nitride semiconductor crystal with ultra-low dislocation density grown epitaxially on a substrate via a particle film with multiple vertically-arranged layers of spheres with innumerable micro- and nano-voids formed among the spheres. The spheres can be composed of a variety of materials, and in particular silica and/or silicon dioxide (SiO2).

2. Description of the Related Art

Group III-Nitride semiconductors, including compounds such as Gallium Nitride (GaN), Aluminum Nitride (AlN), Indium Nitride (InN), Indium Gallium Nitride (InGaN), Aluminum Gallium Nitride (AlGaN) and Indium Aluminum Gallium Nitride (InAlGaN), have the ability of widely controlling the energy gap by regulating the composition ration thereof. As an example, Aluminum Indium Gallium Nitride (AlInGaN)-based compounds, which obey the formula AlₓIn_{y}Ga_{(l-x-y)}N (where 0≦x≦1, 0≦y≦1), act as a direct transition semiconductor and exhibit an energy bandgap in the range from 0.7-0.8 eV to 6.2 eV. Accordingly, utilizing GaN-based compounds in the formation of an active layer makes it possible to realize a light emitting device capable of emitting light of all colors from red-color light down to ultraviolet light.

To apply GaN-based compounds to a light emitting device or other micro-electronic device such as a transistor, a crystal layer having a high quality and high efficiency from the viewpoint of lifetime or lifespan of products may be needed. GaN-based compounds have a hexagonal-wurtzite structure and the low lattice constant of the GaN-based compounds shows a great difference from other main semiconductors (Group III-V and Group II-VI semiconductors etc). This very low lattice constant is very difficult to match to the lattice constant of a substrate crystal (such as sapphire, silicon, silicon carbide, gallium arsenide etc). Generally, if the lattice constant of a substrate crystal differs from the lattice constant of a crystal to be epitaxially grown on the substrate crystal, the resulting growth layer is easily affected by a compressive bending or tensile bending and tends to disadvantageously accumulate an elastic bending energy therein. Although this elastic energy is within an allowable range if the growth layer is thin, the elastic energy may generate an electric potential if the thickness of the growth layer exceeds a certain critical value, thus causing lattice relaxation and resulting in a great amount of electric defects and dislocations in the growth layer, as shown in FIG. 1.

FIG. 1 is a transmission electron microscope (TEM) image of a GaN semiconductor crystal grown on a sapphire substrate using a conventional method. FIG. 1 specifically illustrates examples of threading dislocations propagating mainly along the c-axis of the crystal and dislocation half loops close to the GaN/sapphire interface.

For this reason, selection of a substrate and the epitaxial growth technique employed is important in the growth of AlInGaN-based compounds. These dislocations are harmful in several respects. Firstly, at a high density (i.e., higher than 1×10⁷ cm⁻²), dislocations degrade electronic mobility and electronic properties (photoluminescence intensity, life of carriers). Furthermore, the emergence of surface dislocations results in surface depression. In a laser diode structure based on InGaN multi-quantum wells (MQWs), the dislocations may disturb the order of MQWs and cause non-homogeneous light emission. Finally, metals used for purely resistive contacts may also diffuse through these dislocations and nanotubes.

Because solid GaN substrates of satisfactory size and in significant quantity based on a commercially viable method are not available, Group III-Nitride based components are currently made by heteroepitaxy on substrates such as sapphire, silicon (Si) and silicon carbide (SiC) or others. Amongst the various techniques, Epitaxial Lateral Overgrowth (ELO) is one of the more popular techniques and has been developed for GaN with a large number of variants.

As described in detail in P. Gibart, “Metal organic vapour phase epitaxy of GaN and lateral overgrowth”, Rep. Prog. Phys., vol. 67, pp. 667-715, 2004, the first step is to grow by epitaxy a first layer of GaN on a substrate, and a dielectric mask is then deposited on this layer. The next step is to perform photolithography of openings in this dielectric mask with clearly defined dimensions and crystallographic orientations. Growth epitaxy is continued on the prepared GaN layers starting with on the openings. This resumed growth causes lateral growth of GaN crystals which has the effect of reducing the dislocation density. Through dislocations do not propagate above the mask. However, GaN that is epitaxially grown on the openings of the dielectric mask, consistent with the initial GaN, maintains the same dislocation density as the initial compound. Furthermore, lateral patterns with a lower dislocation density coalesce and, because the initial GaN is in a mosaic pattern, the weak disorientation leads to a region with a high dislocation density in the coalescence plane or the coalescence joint. Consequently, it is impossible to use the entire surface to manufacture optoelectronic components using a conventional ELO process.

FIGS. 2 and 3 are diagrams illustrating the ELO process. FIG. 2 is a diagram illustrating the Epitaxial Layer Overgrowth (ELO) process using a conventional method. A GaN layer is epitaxied (GaN base layer 2) on a substrate 1. A mask 3, composed for example of silicon dioxide (SiO₂), silicon nitride (SiNₓ), aluminum oxide (Al₂O₃) or other material, is deposited, for example by Chemical Vapor Deposition (CVD), Plasma-Assisted CVD, sputtering or other method. Openings are formed on this mask by photolithography, along crystallographic directions and with appropriate dimensions, for example 3 micrometers (μm) openings separated by 7 micrometers (μm) along the [1-100]_{GaN} direction. When growth of GaN is resumed, the deposition first takes place in the openings 5, then laterally above the mask 4. Above the openings 5, GaN in epitaxial contact with the substrate, maintains the same defect density as the base layer 2. The black vertical lines in FIG. 2 represent dislocations. The GaN laterally grows above the mask (overgrowth of GaN 4). Through dislocations do not propagate in this zone. However a coalescence joint 6 forms when the two lateral overgrowth fronts join in the middle of the mask. Therefore, the manufacturing technology for a laser diode on an ELO substrate as described above requires a complex technology because the diode structure needs to be made on overgrowth zones 4, between the coalescence joint and the zone in epitaxial contact with the substrate. This requires an alignment precision on the order of 1 micrometer (μm), which results in a complicated, low-yield and high-cost process.

FIG. 3(a) and FIG. 3(b) illustrate top-view cathode-luminescence (CL) mapping of GaN samples grown using conventional ELO process. Specifically, FIG. 3(a) illustrates two-step-ELO. Dislocations pointing up appear as black points. Lines with a high density of dislocations (white arrows) alternate with lines with a lower density of dislocations (black arrows). The distance between these lines is 5 micrometers (μm). The highly defective lines correspond to the coalescence boundaries in the wings, whereas the other lines correspond to the centre of windows in the dielectric mask. In this example, the density of dislocations over the entire surface is on the order of 2−5×10⁷/cm². FIG. 3(b) illustrates a standard one-step-ELO, as illustrated in FIG. 2. The distribution of emerging dislocations in FIG. 3(a) is denser than FIG. 3(a). The four white arrows still indicate the coalescence boundaries. Above the windows in the dielectric mask (indicated by an asterisk (*)) the defect density is now significantly higher, on the order of 5×10⁸/cm². Even though the two-step ELO results in improved wafer quality compared to one step ELO, it is also significantly more expensive since it requires two patterning and three epitaxial growth steps.

Therefore, there is a need to overcome these and other problems of the prior art and to provide high-quality Group III-Nitride semiconductor crystal with ultra-low dislocation density, free-standing or on foreign substrates, and scalable methods for their manufacturing so as to be utilized for the manufacturing of optoelectronic and microelectronic semiconductor devices of improved performance, increased reliability, operating lifetime, yield and reduced cost.

### BRIEF DESCRIPTION OF THE DRAWINGS

The invention has other advantages and features which will be more readily apparent from the following detailed description of the invention and the appended claims, when taken in conjunction with the accompanying drawings, in which:

FIG. 1 (prior art) is a transmission electron microscope (TEM) image of a GaN semiconductor crystal grown on a sapphire substrate using a conventional method.

FIG. 2 (prior art) is a diagram illustrating the Epitaxial Layer Overgrowth (ELO) process using a conventional method.

FIGS. 3(a)-(b) (prior art) illustrate top-view cathode-luminescence (CL) mapping of GaN samples grown using a conventional ELO process.

FIGS. 4(a)-(c) are schematic diagrams illustrating growth of an ultra-low dislocation density Group III-Nitride semiconductor crystal, according to one embodiment.

FIGS. 5(a)-(b) shows a schematic of a particle film including a single layer of hexagonally close packed spheres formed on the top of a starting substrate, according to one embodiment.

FIGS. 6(a)-(b) illustrate the circular intersections of the top surface of the starting substrate with the spheres in the particle film that is formed on the top of and in contact with the starting substrate, according to one embodiment.

FIGS. 7(a)-(c) are schematic diagrams illustrating the top views of a particle film formed on the top of a starting substrate, according to one embodiment.

FIGS. 8(a)-(d) are schematic cross-sectional views illustrating the various stages of the epitaxial growth of an ultra-low dislocation density Group III-Nitride semiconductor crystal, according to one embodiment.

FIG. 9 is a schematic cross-sectional view illustrating an ultra-low dislocation density Group III-Nitride semiconductor crystal grown according to one embodiment.

FIGS. 10(a)-(c) illustrate various implementations of particle films spun on substrates, according to various embodiments.

FIGS. 11(a)-(c) illustrate an ultra-low dislocation density Group III-Nitride semiconductor crystal epitaxially grown according to various embodiments.

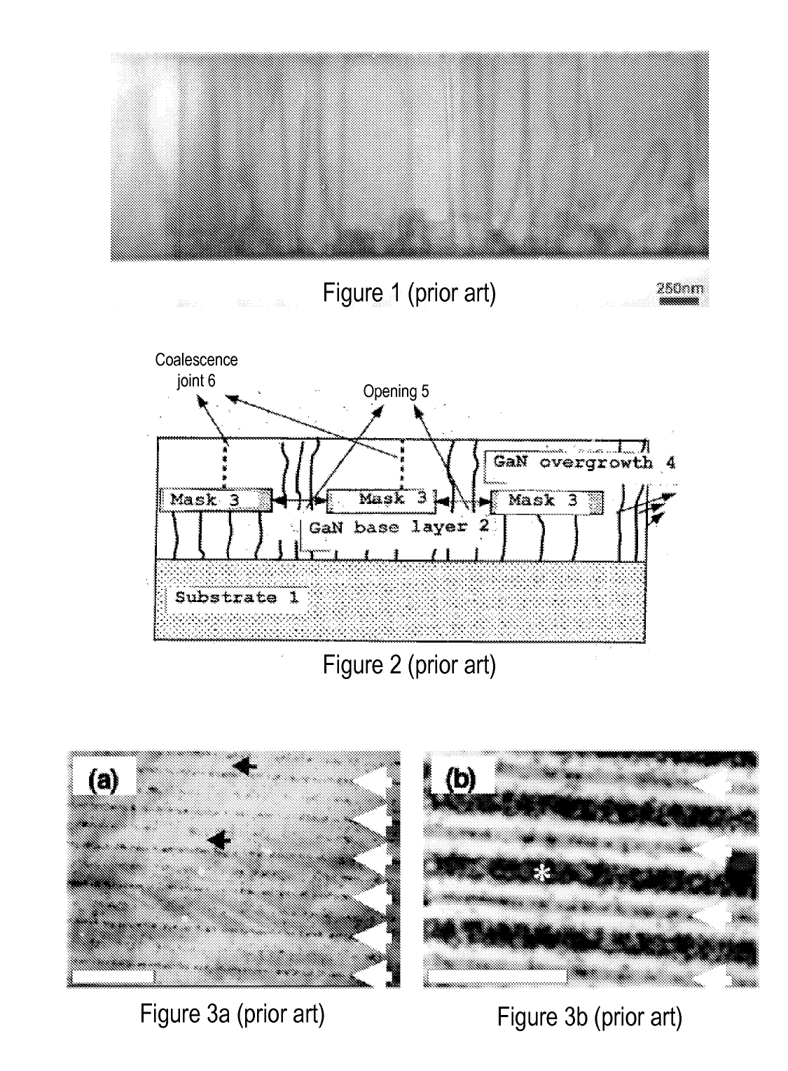

The figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION OF THE PREFERRED EMBODIMENTS

Objectives and advantages of the invention may be obvious from the foregoing description, will be set forth in part in the description that follows, or may be learned by practice of the invention. It is to be understood that both the foregoing description and the following description are exemplary and explanatory only and are not restrictive of the invention, as claimed. The objectives and advantages of the invention will be realized and attained by means of the elements and combinations particularly pointed out in the appended claims. Various embodiments may achieve some, all or none of the following objectives.

One desirable objective is to provide an ultra low defect or dislocation density Group III-Nitride semiconductor crystal in which the strain with the starting substrate is more relaxed and crystal defect or dislocation density is lower than conventional methods, and having characteristics that are generally uniform across the surface of the substrate. The growth of the ultra-low dislocation density Group III-Nitride semiconductor crystal will occur via a particle film composed of a single or multiple layers of spheres containing micro- and/or nano-voids among the spheres. The particle film may be formed on the top of a starting substrate. The voids among the spheres in the particle film are connected to each other to form a network of voids extending from the surface of the starting substrate up to the open space above the particle film, thereby providing the path for the Group III and Group V precursor gases inside the growth chamber to reach the surface of the starting substrate. This allows the growth of the ultra-low dislocation density Group III-Nitride semiconductor crystal via the particle film to occur. On the top of the ultra-low dislocation density Group III-Nitride semiconductor crystal, a device structure comprising a plurality of Group III-Nitride semiconductor epitaxial layers may be subsequently grown.

Another possible objective is to provide such an ultra-low dislocation density Group III-Nitride semiconductor crystal grown on a starting substrate in which the thickness of the ultra-low dislocation density Group III-Nitride semiconductor crystal is sufficient to allow a free-standing ultra-low dislocation density Group III-Nitride semiconductor substrate to be cut out. On the top of the free-standing ultra-low dislocation density Group III-Nitride semiconductor crystal, a device structure comprising a plurality of Group III-Nitride semiconductor epitaxial layers may be subsequently grown.

Yet another possible objective is to provide a Group III-Nitride semiconductor substrate, a Group III-Nitride semiconductor device and fabrication methods thereof, provided with an ultra-low dislocation density Group III-Nitride semiconductor crystal oriented along any of the following crystallographic planes: C(0001), M(1-100), A(11-20), R(1-102), S(10-11) and N(11-23).

Strain with a starting substrate can be relaxed by forming a particle film composed of a single or multiple layers of micro- or nano-spheres arranged vertically with respect to each other, in which particle film innumerable micro- and/or nano-voids are formed among the spheres, and growing a Group III-Nitride semiconductor crystal via the particle film so that a Group III-Nitride semiconductor crystal with much lower dislocation density than conventional means can be obtained. In one embodiment, an ultra-low dislocation density Group III-Nitride semiconductor substrate is fabricated by performing the steps of: forming the particle film composed of spheres on a starting crystal; conducting a treatment for the starting substrate on which the particle film is formed in order to form micro- and/or nano-voids inside the particle film having voids extend from the surface of the particle film to the surface of the starting substrate; and growing an ultra-low dislocation density Group III-Nitride semiconductor crystal via the particle film on the treated starting substrate. The voids among the spheres in the particle film are connected to each other and form a network of voids extending from the surface of the starting substrate up to the open space above the particle film, thereby providing the path for the Group III and Group V precursor gases inside the growth chamber to reach the surface of the starting substrate. This allows the growth of the ultra-low dislocation density Group III-Nitride semiconductor crystal via the particle film to occur.

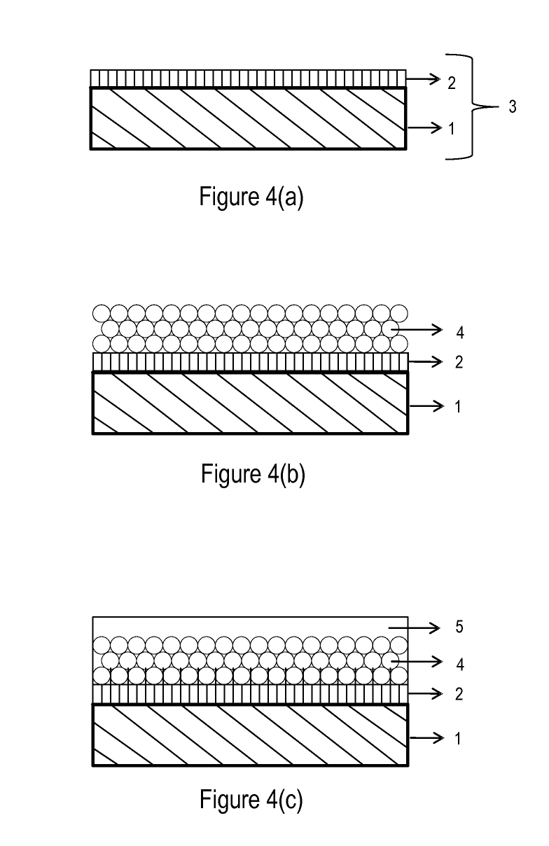

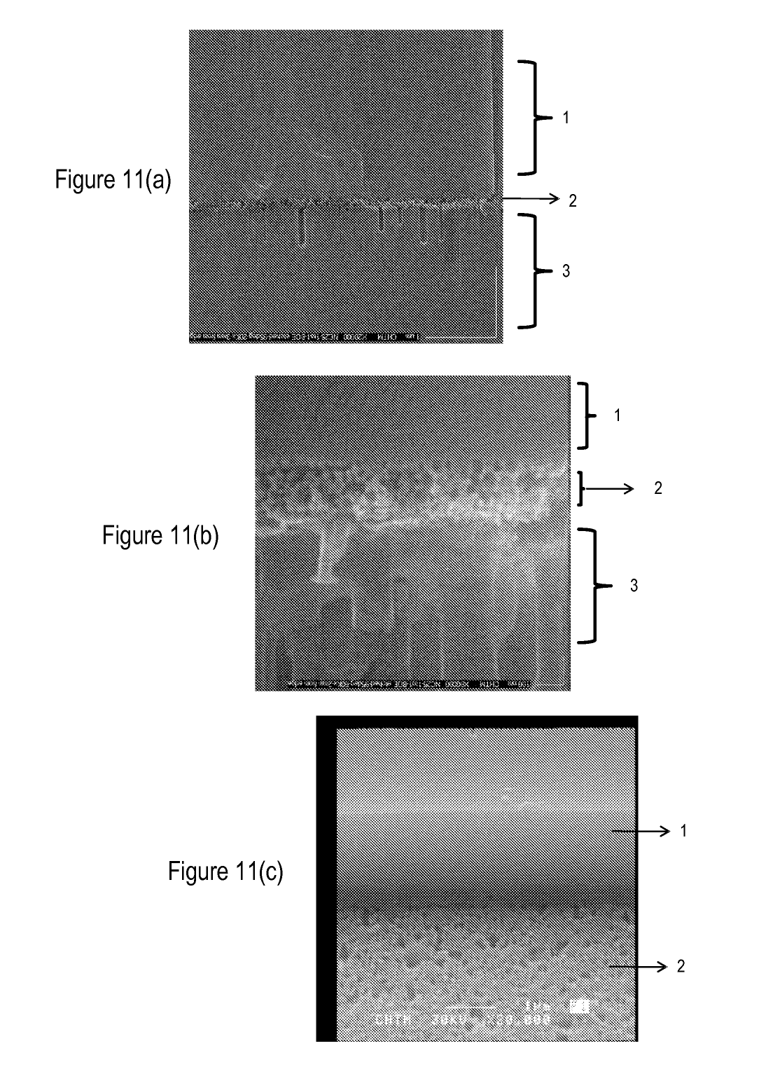

This embodiment is illustrated schematically in FIGS. 4, 8 and 9. The experimental results of the growth of an ultra-low dislocation density Group III-Nitride semiconductor crystal are shown in FIG. 11.

FIGS. 4(a)-(c) are schematic diagrams illustrating growth of an ultra-low dislocation density Group III-Nitride semiconductor crystal 5 via a particle film composed of spheres 4 with micro- and/or nano-voids amongst the spheres 4, according to one embodiment. Specifically, FIG. 4(a) illustrates a starting substrate 3 including a Group III-Nitride semiconductor crystal 2 with high dislocation density grown on an initial substrate material 1 such as sapphire, silicon carbide or silicon. FIG. 4(b) illustrates a spin-coated particle film formed on starting substrate 3. The spin-coated particle film includes multiple layers of spheres 4 provided with innumerable micro- and/or nano-voids among the spheres. FIG. 4(c) illustrates ultra-low dislocation density Group III-Nitride semiconductor crystal 5 via the particle film grown on starting substrate 3. The spheres 4 in the particle film may block and eliminate the significant majority of dislocations and may reduce the dislocation density of the Group III-Nitride semiconductor crystal 5 by several orders of magnitude.

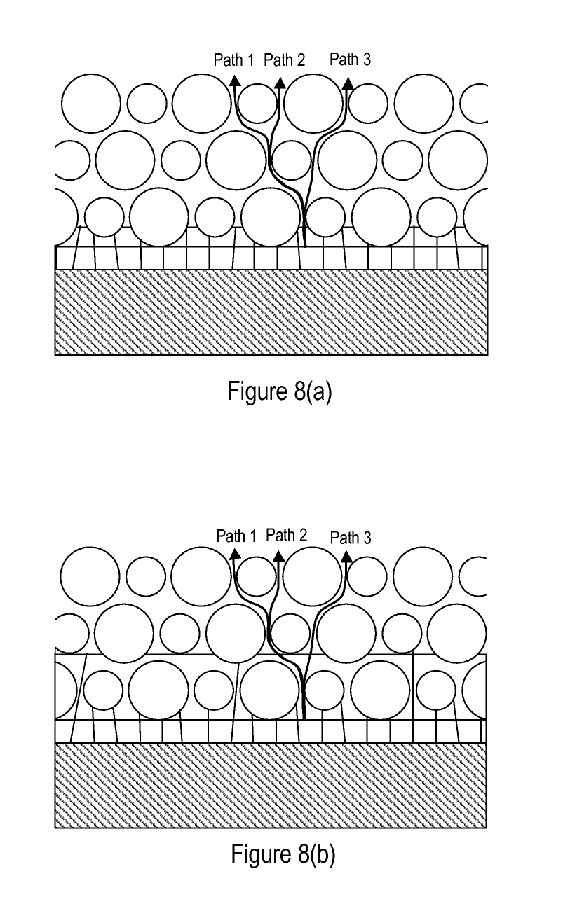

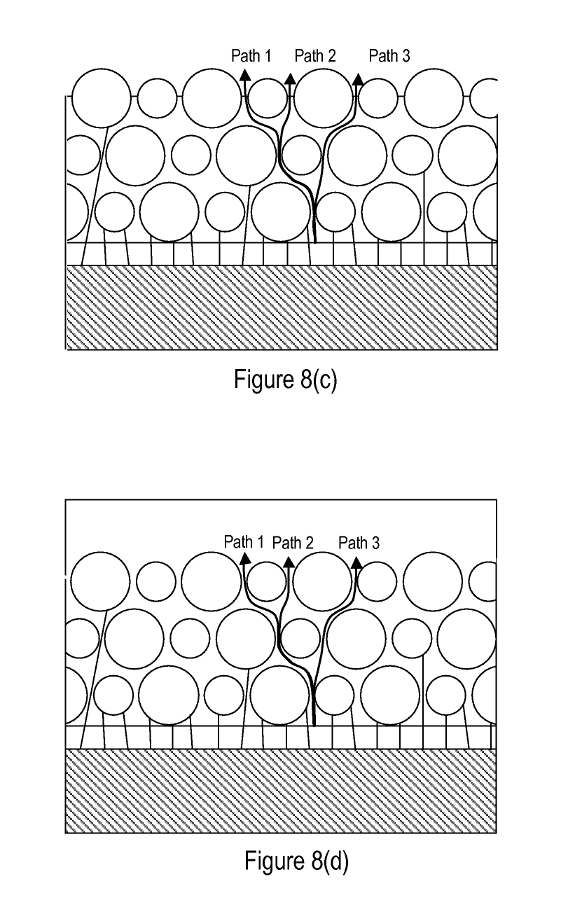

FIGS. 8(a)-(d) are schematic cross-sectional views illustrating the various stages of the epitaxial growth of an ultra-low dislocation density Group III-Nitride semiconductor crystal 3, according to one embodiment. The Group III-Nitride semiconductor crystal 3 is grown via a particle film including multiple layers of spheres 2 with micro- or nano-voids formed on the top of a starting substrate 1. In the example of FIGS. 8(a)-(d), the starting substrate 1 may be a Group III-Nitride semiconductor crystal with a high dislocation density (dislocations are represented by vertical black lines) grown on the top of foreign substrate such as a sapphire substrate. A few exemplary paths of the progressive growth of the ultra-low dislocation density Group III-Nitride semiconductor crystal 3 are illustrated in the sequence of FIGS. 8(a)-(d). As the epitaxial growth of the ultra-low dislocation density Group III-Nitride semiconductor crystal 3 progresses through the network of voids formed among the spheres 2 of the particle film, a large portion of dislocations may be blocked by and terminated on the surface of the spheres 2 composing the particle film, and in turn may release the strain energy associated with the dislocations and significantly reduce the dislocation density in the Group III-Nitride semiconductor crystal 3 grown through and above the particle film. Such a significant reduction of dislocation density in the Group III-Nitride semiconductor crystal 3 is achieved uniformly across the entire surface of the Group III-Nitride semiconductor substrate.

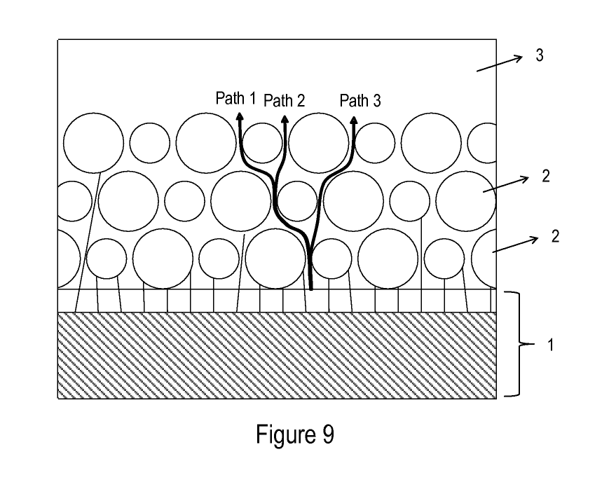

FIG. 9 is a schematic cross-sectional view illustrating an ultra-low dislocation density Group III-Nitride semiconductor crystal 3 grown via a particle film composed of multiple layers of spheres 2 with micro- and/or nano-voids amongst them and formed on a starting substrate 1, according to one embodiment. The termination of the dislocations, which propagate upwards from the starting substrate along the growth direction and appear as vertical black lines in FIG. 9, at the surface of the spheres 2 releases the strain energy associated with the dislocations and reduces the dislocation density in the Group III-Nitride semiconductor crystal 3 significantly. Therefore, an ultra-low dislocation density Group III-Nitride semiconductor crystal 3 may be grown through and above the particle film containing the spheres 2.

FIGS. 11(a)-(c) illustrate an ultra-low dislocation density Group III-Nitride semiconductor crystal 1 epitaxially grown via a particle film 2 including multiple layers of spheres with micro- and/or nano-voids amongst the spheres, according to embodiments of the present invention. The particle film 2 is spin-coated on a starting substrate. The starting substrate is composed of a Group III-Nitride semiconductor crystal 3 with high dislocation density grown on an initial substrate material (not shown), which may be sapphire. FIGS. 11(a) and 11(b) illustrates embodiments where the particle film 2 is a colloidal solution of silica nano-spheres with a size distribution approximately between 20 and 40 nanometers (nm). FIG. 11(c) illustrates an embodiment where the particle film 2 is a colloidal solution of silica nano-spheres with a size distribution approximately between 70 and 100 nanometers (nm).

The starting substrate comprises crystals to be chosen in any combination include, but are not limited to, sapphire (Al₂O₃), silicon (Si), zinc oxide (ZnO), silicon carbide (6H—SiC, 4H—SiC, 3C—SiC), gallium nitride (GaN), aluminum nitride (AlN), Indium Nitride (InN), Aluminum Gallium Nitride (AlGaN), Indium Gallium Nitride (InGaN), Aluminum Indium Nitride (AlInN), Aluminum Indium Gallium Nitride (AlInGaN), gallium arsenide (GaAs), LiAlO₂, LiGaO₂ and MgAlO₄. In addition, a surface of the starting substrate (a forming surface of the particle film) may be used as a non-polar forming surface for obtaining a Group III-Nitride semiconductor crystal in which a surface is a non-polar surface. For example, when the starting substrate is sapphire, the r-plane, a-plane or m-plane may be used as the non-polar forming surfaces.

Preferably, the particle film formed on the starting substrate comprises colloidal particle arrays in two-dimensional and three-dimensional arrangements. One or multiple layers of such particles may be stacked one on the top of each other. The colloidal particle arrays may also comprise micro- and/or nano-spheres of silica or silicon dioxide (SiO₂), silicon nitride (SiN), titania (TiO₂), gold, CdS, Pb, mesoscale ZnS or polymers (for example, polystyrene). Such particles are typically dispersed throughout a chemical liquid carrier. Several commercial vendors offer such products in which colloidal silica is made by growing mono-dispersed, negatively charged, amorphous silica particles in water. OH ions exist at the surface of the particles with an electric double layer formed by alkali ions. Stabilization is achieved by the repulsion between the same negatively charged particles. Disturbance of the charge balance will cause the colloidal silica to aggregate. Preferably, the size of the spheres falls within a range from a few nanometers (e.g., 2 nm) up to several hundred microns (e.g., 200 micrometers (μm)) or larger.

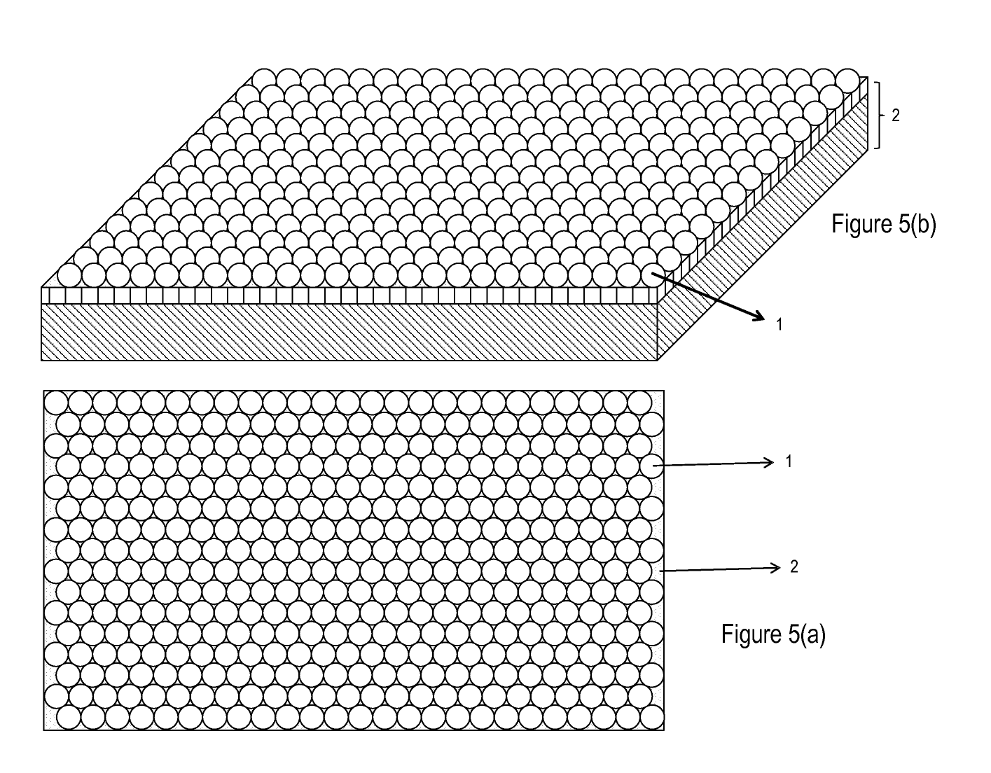

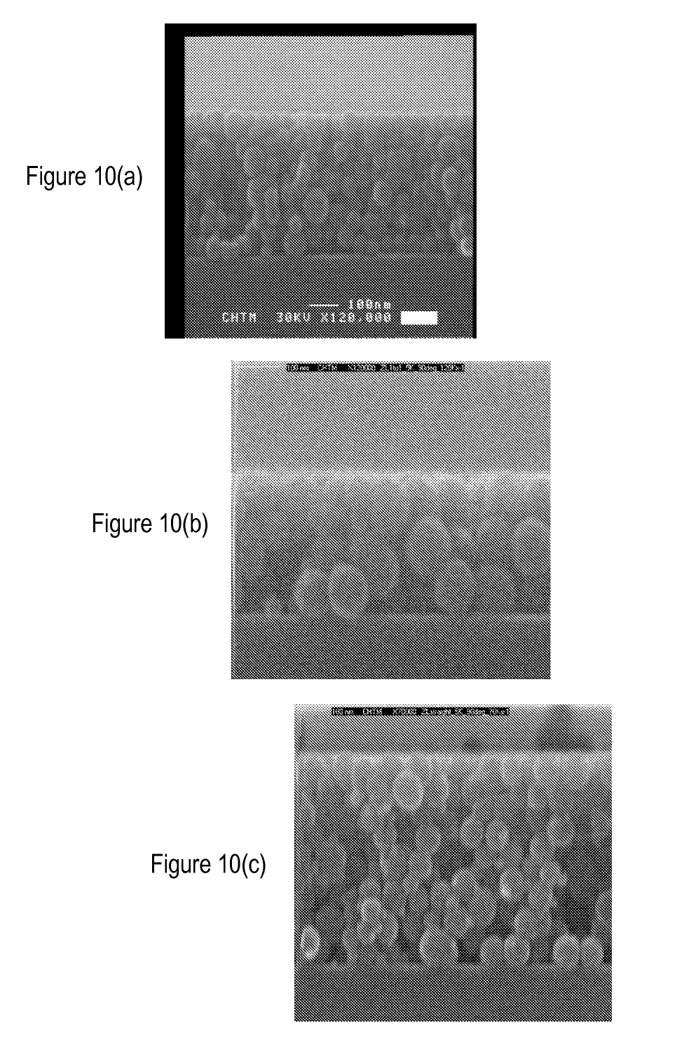

Various experimental implementations of particle films composed of multiple layers of silica spheres are shown in FIG. 10. In addition, drawings that describe the design of particle films include a single or multiple layers of spheres as illustrated in FIGS. 5, 6 and 7.

FIGS. 10(a)-(c) illustrate various implementations of particle films spun on substrates, according to embodiments of the present invention. The particles films include silica spheres with micro- and nano-voids formed among the spheres. The growth of ultra-low dislocation density Group III-Nitride semiconductor crystal proceeds via the micro- or nano-voids that are formed among the spheres in the particle film which is spin-coated on the starting substrate. FIGS. 10(a)-(c) illustrate particle films with multiple layers of spheres.

FIGS. 5(a)-(b) shows a schematic of a particle film including a single layer of hexagonally close packed spheres 1 formed on the top of a starting substrate 2, according to one embodiment. In the embodiment of FIG. 5, the starting substrate 2 is composed of a Group III-Nitride semiconductor crystal with high dislocation density (dislocations are represented by vertical black lines) grown on the top of foreign substrate such as a sapphire or silicon substrate. In FIG. 5, all the spheres 1 are illustrated as being in perfect shape and of the same size. The spheres 1, however, may vary in size and shape, and therefore, the position of each individual sphere 1 and the space between them may also vary.

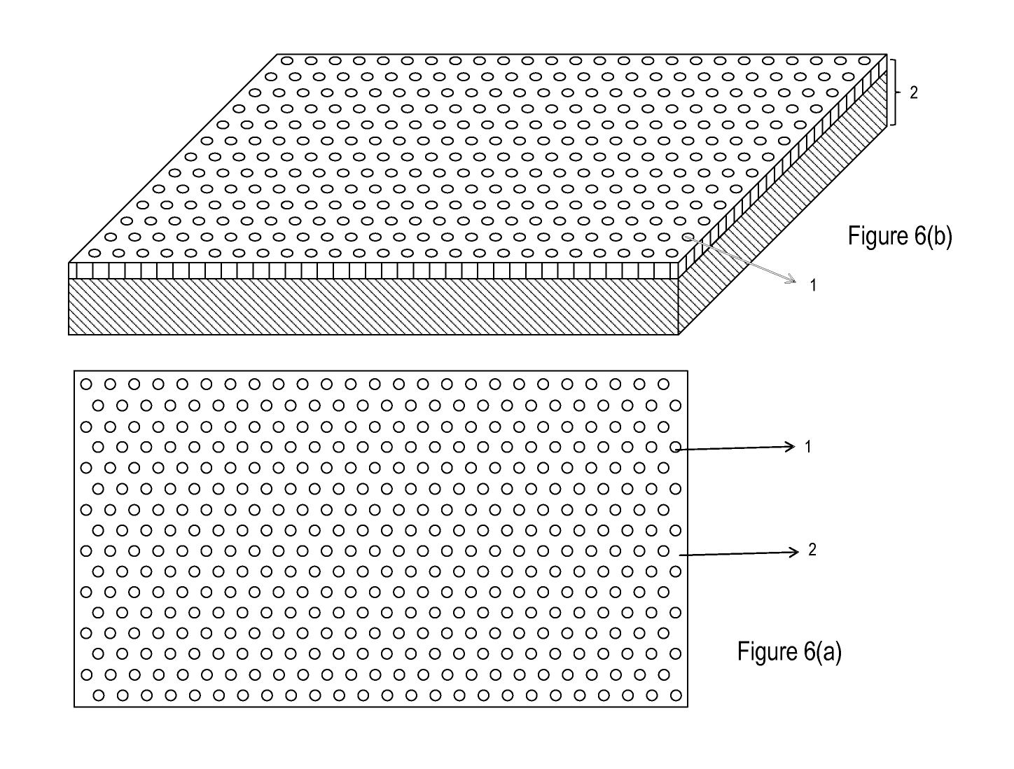

FIGS. 6(a)-(b) illustrate the circular intersections 1 of the top surface of the starting substrate 2 with the spheres in the particle film that is formed on the top of and in contact with the starting substrate 2, according to one embodiment. Specifically, FIG. 6(a) illustrates the top, two-dimensional view. FIG. 6(b) illustrates the side three-dimensional view. The circular intersections 1 denote the sections where the spheres in the particle film are in touch with the top surface of the starting substrate 2. The nucleation and subsequent epitaxial growth of the ultra-low dislocation density Group III-Nitride semiconductor crystal are likely to occur in the areas of the surface of the starting substrate 2 that are in between the circular intersections 1.

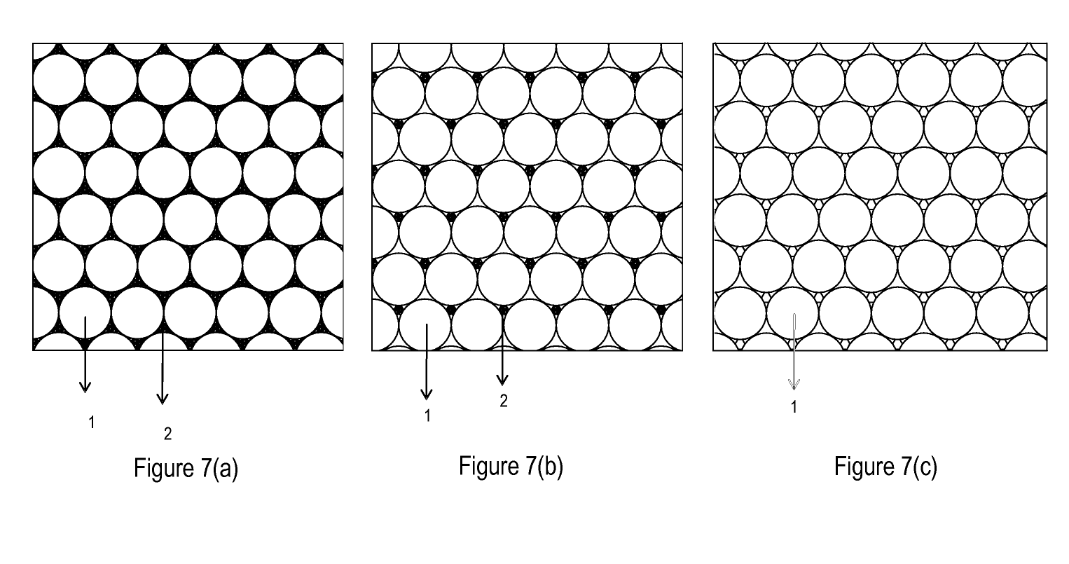

FIGS. 7(a)-(c) are schematic diagrams illustrating the top views of a particle film formed on the top of a starting substrate 2, according to one embodiment. FIG. 7(a) illustrates a single layer of hexagonally close packed spheres 1. FIG. 7b illustrates two layers hexagonally close packed spheres 1. FIG. 7(c) illustrates three layers of hexagonally close packed spheres 1. A particle film of a single layer of spheres 1 may allow only a small percentage (for example, less than 25%) of the surface of starting substrate 2 to be viewed in between the spheres 1 from the top. A particle film of two layers of spheres 1 blocks a portion (e.g., more than 90%) of the surface of the starting substrate 2 when viewed from the top. A particle film composed of three layers of spheres 1 may completely block the entire surface of the starting substrate 2 when viewed from the top. The percentage of the surface of starting substrate 2 blocked by the spheres 1 of the particle film may differ from the embodiment illustrated in FIGS. 7(a)-(c).

A variety of methods such as gravity sedimentation, electrostatic self-assembly, convective deposition, and physical confinement may be used to deposit colloidal particles into two- and three-dimensional patterns. In one embodiment, the spin-coating technique is used. Spin-coating technique has a number of advantages over other self-assembled techniques for the formation of particle films. First, it is rapid and highly manufacturable. Second, spin-coating may be applied to large-diameter substrates. Third, spin-coating is applicable to both large and small diameter spheres. For large spheres, the spin-coating technique overcomes the rapid gravitational sedimentation encountered with other deposition methods. For small spheres, the particle film using the spin-coating technique has high uniformity and tunable thickness over wafer-scale areas.

In one embodiment, the spin-coating process for a particle film (more specifically for a homogeneous material such as colloidal silica spheres) includes the following four stages: (i) deposition, (ii) spin-up, (iii) spin-off, and (iv) evaporation, as described in D. Xia, D. Li, Z. Ku, Y. Luo and S. R. J. Brueck, “Top-Down Approaches to the Formation of Silica Nanoparticle Patterns”, Langmuir, vol. 23, pp. 5377-5385, 2007. An excess of the liquid solution is dispensed on the surface of the wafer during the deposition stage. In the spin-up stage, the liquid flows radially outward. In the spin-off stage, excess liquid flows to the perimeter and leaves as droplets. As the film thins, the rate of removal of excess liquid by spinning slows down because the viscosity increases with the increased concentration of the non-volatile components (such as the silica spheres). Finally, evaporation takes over as the primary mechanism of thinning During spin-up, inertia overwhelms the force of gravity. During spin-off, the tendency to form uniform thickness of colloidal solution arises due to the balance between the two main forces: inertia that drives flow radially outward, and viscous force (friction) that acts radially inward. In general the viscosity of many of these solutions has been reported to be a power-law function of the concentration.

The spinning procedure may create a steady forced convection of the vapor above the substrate. The evaporation rate in spin coating tends to be uniform. A spun film arrives at its final thickness by evaporation when the film becomes so thin that its radial flow is halted. According to this model for spin coating, the final thickness for Newtonian fluids (linear relationship between shear stress and shear rate) can be represented as:

$${h}_{final} = {{c}_{0} ( \frac{3 ηe}{2 {ρ}_{A}^{0} {ω}^{2} ( 1 - {c}_{0} )} )}^{1 / 3} \qquad ( 1 )$$

where, cₒ is the initial concentration of the non-volatile components (e.g. silica spheres for a colloidal silica solution), η is the viscosity, e is the evaporation rate that depends on the mass transfer coefficient, pA° is the initial value of the mass of volatile solvent per unit volume, and ω is the spin speed. This model provides useful insight into the spin coating deposition of nano- or micro-spheres (of diameter comparable to the particle film thickness) from a colloidal suspension.

The evaporation rate, e, in equation (1) depends strongly on how fast the vapor phase above the liquid is removed; and therefore, dependent on the spin speed. Typically, the evaporation rate is proportional to the square root of the spin speed. The final thickness of the silica nanoparticle films, obtained from colloidal silica solutions, is a function of spin speed, concentration and particle size on a wafer. The film thickness is inversely proportional to the square root of the spin speed, which is in line with the model prediction (equation 1). Both the packing density and the particle size distribution impact the observed film thicknesses. As the water evaporates past each layer of nanoparticles through spinning of the wafer or additional heat treatment, capillary forces drive the spheres into contact and form the final pattern; both particle size distributions and defects in the pattern lead to empty spaces among particles so that the final thickness deviates from ideal, hexagonal, close-packed digital expectations. In addition to the control of nanoparticle film thickness with concentration and spin speed, multiple cycles of spin coating processing may be used to control the film thickness. There is a linear relationship between particle film thickness and the number of cycles of spin-coating. Therefore, the nanoparticle film thickness may be controlled by changing the spin speed, concentration, particle size and number of cycles of spin-coating, as shown in FIG. 10.

The particle film provides voids among the spherical particles that are interconnected and penetrate to the surface of the starting substrate so that the growth of the ultra-low dislocation density Group III-Nitride semiconductor crystal may occur, as shown and described in FIGS. 8 and 9. The thickness of the particle film is preferably between 5 nm to 10000 micrometers (μm).

It is preferable that the voids formed inside the particle film between the spheres are homogeneously distributed in the particle film. According to this, the ultra-low dislocation density Group III-Nitride semiconductor crystal can be homogeneously grown on the starting substrate.

A film thickness of the ultra-low dislocation density Group III-Nitride semiconductor crystal is preferably 50 nm or more. It is also desirable that the surface is substantially flattened. By providing a film thickness of 50 nm or more, adjacent nuclei of the initial growth in the Group III-Nitride semiconductor crystal, which are generated from inside the voids provided in the particle film, are bound to each other so that the entire surface can be flattened. The upper value of the film thickness of the Group III-Nitride semiconductor film is not limited. When the Group III-Nitride semiconductor crystal is thinner than 50 nm, many pits or steps appear on the crystal surface and it may become an obstacle to fabricate a device by using the obtained crystal.

It is preferable to selectively generate the semiconductor nuclei from inside of the voids formed inside the particle film at the initial growth stage in the process of growing the ultra-low dislocation density Group III-Nitride semiconductor crystal. The micro voids between the spheres in the particle film may provide the nuclei generating sites at the initial growth stage when conducting the crystal growth of the Group III-Nitride semiconductor crystal. The voids among the spheres in the particle film may be connected to each other and may form a network of voids extending from the surface of the starting substrate up to the open space above the particle film, thereby providing the path for the gaseous materials that are used as reactants during the epitaxial growth. The gaseous materials include, for example, Trimethylgallium (TMG), trimethylaluminum (TMA), Trimethylindium (TMI), ammonia (NH₃) to move on or diffuse towards the surface of the starting substrate through the voids so that the growth of the ultra-low dislocation density Group III-Nitride semiconductor crystal via the particle film can occur. The micro- or nano-spheres inside the particle film are arranged in multiple layers and effectively eliminate, block or annihilate the vast majority of dislocations in the Group III-Nitride semiconductor crystal grown via the particle film on the starting substrate through the termination of dislocations on the surface of the spheres. Therefore, the particle film having the micro- or nano-voids among the spheres has the effect of relaxing the strain, due to the lattice mismatch and difference of thermal expansion coefficients between the starting substrate and the Group III-Nitride semiconductor crystal, and as a result it is possible to provide a Group III-Nitride semiconductor film in which the occurrence of crystal dislocations or defects is ultra low (by several orders of magnitude compared to the case where the particle film is not provided) and warping is small. In addition, even if a thick film crystal, for example, of 1 millimeter (mm) or more in thickness, is grown, no cracking is likely to occur in the crystal. Accordingly, it is possible to fabricate an ultra low dislocation density Group III-Nitride semiconductor crystal as a self-standing substrate by growing such crystal of 1 mm or more in thickness and cutting out a part of the grown Group III-Nitride semiconductor crystal.

Such an ultra-low dislocation density Group III-Nitride semiconductor crystal can be broadly used as a substrate for the epitaxial growth of a Group III-Nitride optoelectronic or microelectronic device consisting of a plurality of semiconductor epitaxial layers. Particularly, when used as substrate for a laser diode or a high power light emitting diode device, a high quality Group III-Nitride semiconductor crystal with ultra low dislocation density allows fabrication of a device with high reliability, high performance, longer operating lifetime, higher yield and significantly lower cost.

In addition, by providing a surface of the starting substrate (a forming surface of the particle film) as a non-polar forming surface, it is possible to provide a Group III-Nitride semiconductor substrate, a substrate for a Group III-Nitride semiconductor device and fabrication methods thereof, each of which is provided with an ultra-low dislocation density Group III-Nitride semiconductor crystal having a non-polar surface at its surface.

The foregoing description of various embodiments of the invention has been presented for purposes of illustration and description. It is not intended to be exhaustive or to limit the invention to the precise form disclosed and many modifications and variations that may be apparent to a person skilled in the art are intended to be included within the scope of the invention as defined by the accompanied claims.

What is claimed is:

1. A method for making a semiconductor substrate, comprising the steps of:
forming a three dimensional multi-layer particle film on a starting substrate;
treating the starting substrate to form micro- and/or nano-voids, the voids being cross-connected and extending from a top surface of the particle film to a surface of the starting substrate underneath the particle film;
growing a Group III-Nitride semiconductor crystal via the particle film on the treated starting substrate, the particle film causing elimination, blocking and/or annihilation of dislocations in the Group III-Nitride semiconductor crystal.

2. The method of making the semiconductor substrate according to claim 1, wherein a defect or dislocation density of the Group III-Nitride semiconductor crystal is less than 1×10⁸ defects or dislocations per square centimeter (/cm²).

3. The method of making the semiconductor substrate according to claim 1, wherein the starting substrate is chosen from a group consisting of sapphire, ZnO, 6H—SiC, 4H—SiC, 3C—SiC, GaN, AN, InN, AlGaN, InGaN, AlInN, AlInGaN, LiAlO₂, LiGaO₂, MgAlO₄, Si, HfB₂ and GaAs, or other compound semiconductors, organic or inorganic materials.

4. The method of making the semiconductor substrate according to claim 1, wherein the particle film comprises at least one layer of at least one element selected from a group consisting of silica/silicon dioxide (SiO₂), silicon nitride (SiN), titania (TiO₂), gold, CdS, Pb, mesoscale ZnS, and polymers.

5. The method of making the semiconductor substrate according to claim 1, wherein the step of forming a three dimensional multi-layer particle film on a starting substrate is selected from a group of consisting of spin-coating the particle film on the starting substrate, spraying, gravity sedimentation, self-assembly, physical confinement, and deposition of the particle film into random or periodic two-dimensional or three-dimensional patterns on the starting substrate.

6. The method of making the semiconductor substrate according to claim 1, wherein the particle film comprises at least one layer of spheres with a diameter between 2 nanometers (nm) and 2000 micrometers (μm), or at least one layer of spherical multi-faceted particles, polyhedra or polyhedrons, with a diameter between 2 nanometers (nm) and 2000 micrometers (μm).

7. The method of making the semiconductor substrate according to claim 1, wherein a thickness of the particle film is between 5 nm and 10000 micrometers (μm).

8. The method of making the semiconductor substrate according to claim 1, wherein a total volume of the voids provided inside the particle film is 99.9% or less of the volume of the particle film.

9. The method of making the semiconductor substrate according to claim 1, wherein semiconductor nuclei are selectively generated from inside of the voids formed among the spheres in the particle film at an initial growth stage in the process of growing the Group III-Nitride semiconductor crystal.

10. The method of making the semiconductor substrate according to claim 1, wherein the step of growing the Group III-Nitride semiconductor crystal is performed by a process selected from a group consisting of (a) Metal Organic Chemical Vapor Deposition (MOCVD); (b) Vapor Phase Epitaxy; (c) Hydride Vapor Phase Epitaxy (HVPE); (d) OrganoMetallic pyrolysis in Vapor Phase Epitaxy (OMVPE); (e) Close Space vapor Transport (CSVT); and (f) Molecular Beam Epitaxy (MBE).

11. The method of making the semiconductor substrate according to claim 1, wherein the Group III-Nitride semiconductor crystal is chosen from a group consisting of Gallium Nitride (GaN), Aluminum Nitride (AlN), Indium Nitride (InN), Aluminum Gallium Nitride (AlGaN), Indium Gallium Nitride (InGaN), and Indium Aluminum Nitride (InAlN), and Aluminum Indium Gallium Nitride (AlInGaN).

12. The method of making the semiconductor substrate according to claim 1, wherein the group III-Nitride semiconductor crystal is doped either positively or negatively using a doping substance chosen from a group consisting of magnesium, zinc, beryllium, carbon, silicon, oxygen, tin and germanium, or other elements.

13. The method of making the semiconductor substrate according to claim 1, wherein a thickness of the Group III-Nitride semiconductor crystal is 50 nm or more and a surface thereof is substantially flattened.

14. The method of making the semiconductor substrate according to claim 1, wherein a surface of the starting substrate is a non-polar forming surface for providing a growth surface for the Group III-Nitride semiconductor crystal, and the growth surface of the Group III-Nitride semiconductor crystal is a non-polar surface.

15. The method of making the semiconductor substrate according to claim 1, wherein the step of growing a Group III-Nitride semiconductor crystal comprises forming an optoelectronic or microelectronic device structure consisting of a plurality of Group III-Nitride semiconductor epitaxial layers.

16. The method of making the semiconductor substrate according to claim 1, wherein a part of the Group III-Nitride semiconductor crystal is cut out to provide a Group III-Nitride semiconductor self-standing substrate after growing the Group III-Nitride semiconductor crystal to have a thickness of 10 micrometers (μm) or more.

17. The method of making the semiconductor substrate according to claim 1, wherein a part of the Group III-Nitride semiconductor crystal is cut out to provide a Group III-Nitride semiconductor self-standing substrate after growing the Group III-Nitride semiconductor crystal to have a thickness of 10 micrometers (μm) or more, and additionally the step of growing the Group III-Nitride semiconductor crystal comprises forming an optoelectronic or microelectronic device structure consisting of a plurality of Group III-Nitride semiconductor epitaxial layers.

18. A semiconductor substrate comprising:
a three dimensional multi-layered particle film formed on a treated starting substrate and consisting of cross-connected micro- and/or nano-voids extending from a top surface of the particle film to a surface of the starting substrate underneath the particle film; and
a Group III-Nitride semiconductor crystal grown on the treated starting substrate via the particle film in which voids are provided or formed, and the particle film causing elimination, blocking and/or annihilation of dislocations in the Group III-Nitride semiconductor crystal.

19. The semiconductor substrate according to claim 18, wherein a defect or dislocation density of the Group III-Nitride semiconductor crystal is less than 1×10⁸ defects or dislocations per square centimeter (/cm²).

20. The semiconductor substrate according to claim 18, wherein the starting substrate is selected from a group consisting of sapphire, ZnO, 6H—SiC, 4H—SiC, 3C—SiC, GaN, AlN, InN, AlGaN, InGaN, AlInN, AlInGaN, LiAlO₂, LiGaO₂, MgAlO₄, Si, HfB₂ and GaAs.

21. The semiconductor substrate according to claim 18, wherein the particle film comprises at least one layer of at least one element selected from a group consisting of silica/silicon dioxide (SiO₂), silicon nitride (SiN), titania (TiO₂), gold, CdS, Pb, mesoscale ZnS and polymers (for example, polystyrene).

22. The semiconductor substrate according to claim 18, wherein the particle film comprises at least one layer of spheres with a diameter between 2 nm and 2000 micrometers (μm), or at least one layer of spherical multi-faceted particles, polyhedra or polyhedrons, with a diameter between 2 nanometers (nm) and 2000 micrometers (μm).

23. The semiconductor substrate according to claim 18, wherein a thickness of the particle film is between 5 nm and 10000 micrometers (μm).

24. The semiconductor substrate according to claim 18, wherein the Group III-Nitride semiconductor crystal is selected from a group consisting of GaN, InN, AlN, AlGaN, InGaN, AlInN, and AlInGaN.

25. The semiconductor substrate according to claim 18, wherein the group III-Nitride semiconductor crystal is doped positively or negatively using a doping substance selected from a group consisting of magnesium, zinc, beryllium, carbon, silicon, oxygen, tin and germanium.

26. The semiconductor substrate according to claim 18, wherein a thickness of the Group III-Nitride semiconductor crystal is 50 nm or more and the surface thereof is substantially flattened.

27. The semiconductor substrate according to claim 18, wherein a surface of the starting substrate is a non polar forming surface for providing a growth surface for the Group III-Nitride semiconductor crystal, and the growth surface of the Group III-Nitride semiconductor crystal is a non polar surface.

28. The semiconductor substrate according to claim 18, further comprising an optoelectronic or microelectronic device structure consisting of a plurality of Group III-Nitride semiconductor epitaxial layers formed in the process of growing the Group III-Nitride semiconductor crystal.

29. The semiconductor substrate according to claim 18, wherein a part of the Group III-Nitride semiconductor crystal is cut out to provide a Group III-Nitride semiconductor self-standing substrate after growing the Group III-Nitride semiconductor crystal to have a thickness of 10 micrometers (μm) or more.

30. The semiconductor substrate according to claim 18, wherein a part of the Group III-Nitride semiconductor crystal is cut out to provide a Group III-Nitride semiconductor self-standing substrate after growing the Group III-Nitride semiconductor crystal to have a thickness of 10 micrometers (μm) or more, and further comprising an optoelectronic or microelectronic device structure consisting of a plurality of Group III-Nitride semiconductor epitaxial layers formed in the process of growing the Group III-Nitride semiconductor crystal.
